(19) United States
(12) Patent Application Publication
(10) Pub. No.: US 2024/0128410 A1
(43) Pub. Date: Apr. 18, 2024

(54) DISPLAY PANEL AND METHOD OF MANUFACTURING THE SAME

(71) Applicant: Samsung Display Co., Ltd., Yongin-si (KR)

(72) Inventors: Soyeon Yoon, Yongin-si, Gyeonggi-do (KR); Junghun Noh, Yongin-si, Gyeonggi-do (KR); Kiseong Seo, Yongin-si, Gyeonggi-do (KR); Jaegwang Um, Yongin-si, Gyeonggi-do (KR); Juwon Yoon, Yongin-si, Gyeonggi-do (KR); Sanghyun Lee, Yongin-si, Gyeonggi-do (KR)

(73) Assignee: Samsung Display Co., Ltd., Yongin-si (KR)

(21) Appl. No.: 18/354,252

(22) Filed: Jul. 18, 2023

(30) Foreign Application Priority Data
Oct. 12, 2022 (KR) 10-2022-0130954

(51) Int. Cl. H01L 33/40; H01L 25/16; H01L 33/58

(52) U.S. Cl. CPC H01L 33/405; H01L 25/167; H01L 33/58; H01L 2933/0016; H01L 2933/0058

(57) ABSTRACT

A display panel includes a substrate, a first electrode disposed on the substrate, a pixel-defining layer disposed on the first electrode and including an opening exposing at least a portion of the first electrode, a micro light-emitting element electrically connected to the first electrode, and a reflector disposed on the first electrode and covering at least a portion of a side surface of the micro light-emitting element.

### CROSS-REFERENCE TO RELATED APPLICATION(S)

This application claims priority to and benefits of Korean Patent Application No. 10-2022-0130954 under 35 U.S.C. § 119, filed on Oct. 12, 2022, in the Korean Intellectual Property Office (KIPO), the entire contents of which are incorporated by herein reference.

### BACKGROUND

### 1. Technical Field

The disclosure relates to a display panel with enhanced light efficiency and a method of manufacturing the display panel.

### 2. Description of the Related Art

A liquid crystal display (LCD) and an organic light emitting diode (OLED) are widely used in a display apparatus. Recently, a technology for manufacturing a high resolution display apparatus using a micro light emitting diode (LED) has been spotlighted. In order to manufacture such a high-resolution display apparatus, a method for coupling high-efficiency micro LEDs manufactured in the form of a micro chip to an electrode has been used. Research has been conducted to enhance the light efficiency in a micro LED display apparatus.

### SUMMARY

The related art has described that the light efficiency of a micro light emitting diode (LED) in a micro LED display apparatus is low.

The disclosure includes a display panel having high light efficiency by increasing the reflectivity of light emitted by a micro light emitting diode (LED) in a micro LED display panel, and a method of manufacturing the display panel.

However, this objective is just an example, and the scope of the disclosure is not limited thereby.

Additional aspects will be set forth in part in the description which follows and, in part, will be apparent from the description, or may be learned by practice of the embodiments of the disclosure.

According to an aspect of the disclosure, a display panel may include a substrate, a first electrode disposed on the substrate, a pixel-defining layer disposed on the first electrode and including an opening exposing at least a portion of the first electrode, a micro light-emitting element electrically connected to the first electrode, and a reflector disposed on the first electrode and covering at least a portion of a side surface of the micro light-emitting element.

According to an aspect of the disclosure, the reflector may have a first reflectivity, and the first electrode may have a second reflectivity lower than the first reflectivity.

According to an aspect of the disclosure, the reflector may be disposed directly on a top surface of the first electrode.

According to an aspect of the disclosure, the reflector may include a first metal.

According to an aspect of the disclosure, the first metal may be silver (Ag), aluminum (Al), a compound of silver, or a compound of aluminum.

According to an aspect of the disclosure, the reflector may include a conductive oxide.

According to an aspect of the disclosure, the reflector may include at least two layers including a first layer including the first metal and a second layer including a conductive oxide.

According to an aspect of the disclosure, a length of which the reflector and the side surface of the micro light-emitting element contact each other in a cross-sectional view may be in a range of about 0.1 μm to about 5 μm.

According to an aspect of the disclosure, the first electrode and the micro light-emitting element may be electrically connected to each other by eutectic bonding.

According to an aspect of the disclosure, the first electrode may include a second metal different from the first metal.

According to an aspect of the disclosure, the second metal may be copper (Cu), tin (Sn), gold (Au), a compound of copper, a compound of tin, or a compound of gold.

According to an aspect of the disclosure, the display panel may further include a black matrix disposed on the pixel-defining layer, and an insulating layer disposed on the reflector and a portion of the pixel-defining layer.

According to an aspect of the disclosure, the insulating layer may be disposed between the micro light-emitting element and the black matrix.

According to an aspect of the disclosure, the display panel may further include a second electrode disposed on the insulating layer and the micro light-emitting element.

According to an aspect of the disclosure, the second electrode may be disposed on the black matrix.

According to an aspect of the disclosure, the second electrode may be disposed between the pixel-defining layer and the black matrix.

According to an aspect of the disclosure,
a method of manufacturing a display panel may include forming a first electrode on a substrate, forming, on the first electrode, a pixel-defining layer including an opening exposing at least a portion of the first electrode, electrically connecting a micro light-emitting element to the first electrode, forming a material for forming a reflector on the pixel-defining layer, the first electrode, and the micro light-emitting element, forming a patterning layer in the opening of the pixel-defining layer in which the micro light-emitting element is electrically connected and covered with the material for forming the reflector, etching and removing an exposed portion of the material for forming the reflector, and removing the patterning layer.

According to an aspect of the disclosure, the method may further include forming an insulating layer on the pixel-defining layer and the reflector, and forming a second electrode on the insulating layer.

According to an aspect of the disclosure, the method may further include forming a black matrix on the pixel-defining layer. The second electrode may be formed on the black matrix.

According to an aspect of the disclosure, the method may further include forming an insulating layer on the pixel-defining layer and the reflector, forming a second electrode on the pixel-defining layer and the insulating layer, and forming a black matrix on the second electrode.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic plan view of a display panel according to an embodiment;

FIG. 2A is a schematic cross-sectional view of the display panel taken along line I-I′ of FIG. 1, according to an embodiment;

FIG. 2B is a schematic cross-sectional view of the display panel taken along line I-I′ of FIG. 1, according to an embodiment;

FIG. 3 is a schematic cross-sectional view of a display panel according to an embodiment;

FIGS. 4 through 13 are cross-sectional views schematically illustrating a method of manufacturing a display panel according to an embodiment; and

FIGS. 14 through 20 are schematic cross-sectional views schematically illustrating a method of manufacturing a display panel according to another embodiment.

### DETAILED DESCRIPTION OF THE EMBODIMENTS

Reference will now be made in detail to embodiments, which are illustrated in the accompanying drawings, wherein like reference numerals refer to like elements throughout. In this regard, the embodiments may have different forms and should not be construed as being limited to the descriptions set forth herein. Accordingly, the embodiments are merely described below, by referring to the figures, to explain aspects of the description.

Since various modifications and various embodiments of the disclosure are possible, specific embodiments are illustrated in the drawings and described in detail in the detailed description. Effects and features of the disclosure, and a method of achieving them will be apparent with reference to embodiments described below in detail in conjunction with the drawings. However, the disclosure is not limited to the embodiments disclosed herein, but may be implemented in a variety of forms.

Although the terms “first”, “second”, etc. may be used herein to describe various types of elements, these elements should not be limited by these terms. These terms are used to distinguish one element from another element. Thus, a first element discussed below could be termed a second element without departing from the teachings of the disclosure.

The terminology used herein is for the purpose of describing particular embodiments and is not intended to be limiting. As used herein, the singular forms, “a”, “an”, and “the” are intended to include the plural forms as well, unless the context clearly indicates otherwise. Moreover, the terms “comprises”, “comprising”, “includes”, and/or “including” when used in this specification, specify the presence of stated features, integers, steps, operations, elements, components, and/or groups thereof, but do not preclude the presence or addition of one or more other features, integers, steps, operations, elements, components, and/or groups thereof.

In the drawings, for convenience of explanation, the sizes of components may be exaggerated or reduced. For example, since the size and thickness of each component shown in the drawings are arbitrarily indicated for convenience of explanation, the disclosure is not necessarily limited to the illustration.

In the case where some embodiments may be implemented in the specification, a specific process order may be performed differently from the order described. For example, two processes described in succession may be substantially performed at the same time, or in an opposite order to an order to be described.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within ±30%, 20%, 10%, 5% of the stated value.

When an element, such as a layer, is referred to as being “on”, “connected to”, or “coupled to” another element or layer, it may be directly on, connected to, or coupled to the other element or layer or intervening elements or layers may be present. When, however, an element or layer is referred to as being “directly on”, “directly connected to”, or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

The x-axis, the y-axis, and the z-axis are not limited to three axes on a Cartesian coordinate system, and may be interpreted in a broad sense including the same. For example, the x-axis, the y-axis, and the z-axis may be perpendicular to each other, but may refer to different directions that are not orthogonal to each other.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

Hereinafter, embodiments of the disclosure will be described in detail with reference to the accompanying drawings, and same reference numerals are used for same or corresponding components when describing the disclosure with reference to the drawings, and a redundant description thereof is omitted.

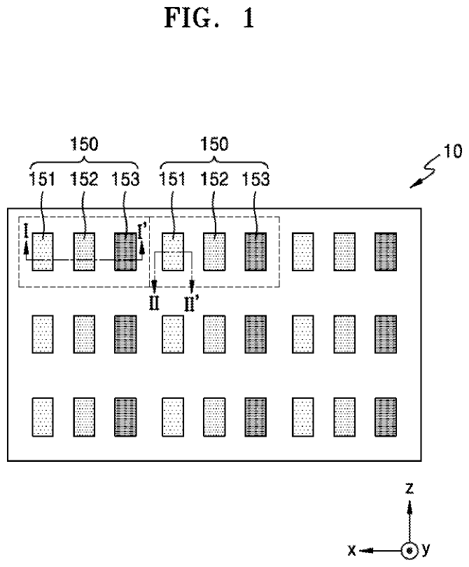

FIG. 1 is a schematic plan view of a display panel 10 according to an embodiment.

Referring to FIG. 1, the display panel 10 may include multiple unit pixels 150. In FIG. 1, 9 unit pixels 150 are shown, but the disclosure is not limited thereto. In order for a display apparatus to implement a color image, each of the unit pixels 150 may include pixels having different colors 151, 152, and 153. For example, each of the unit pixels 150 may include a first pixel 151, a second pixel 152, and a third pixel 153, each having different colors. In an embodiment, the first pixel 151, the second pixel 152, and the third pixel 153 may be blue, green, and red pixels. However, embodiments of the disclosure are not limited thereto.

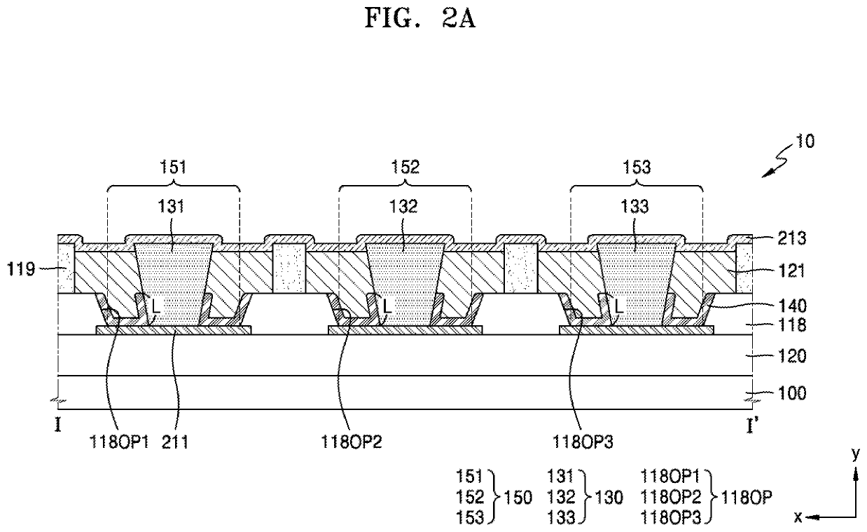

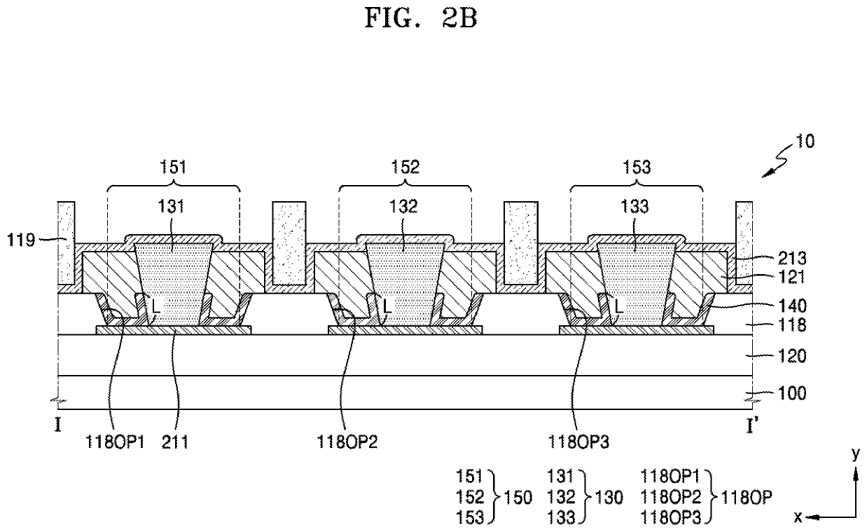

FIG. 2A is a schematic cross-sectional view of the display panel taken along line I-I′ of FIG. 1, according to an embodiment. FIG. 2B is a schematic cross-sectional view of the display panel taken along line I-I′ of FIG. 1, according to an embodiment.

Referring to FIG. 2A, a first electrode 211, a pixel-defining layer 118, a reflector 140, a black matrix 119, an insulating layer 121, micro light-emitting elements 130, and a second electrode 213 may be arranged on a substrate 100. In an embodiment, the display panel 10 may include a first electrode 211, a pixel-defining layer 118, a reflector 140, a black matrix 119, an insulating layer 121, micro light-emitting elements 130, and a second electrode 213.

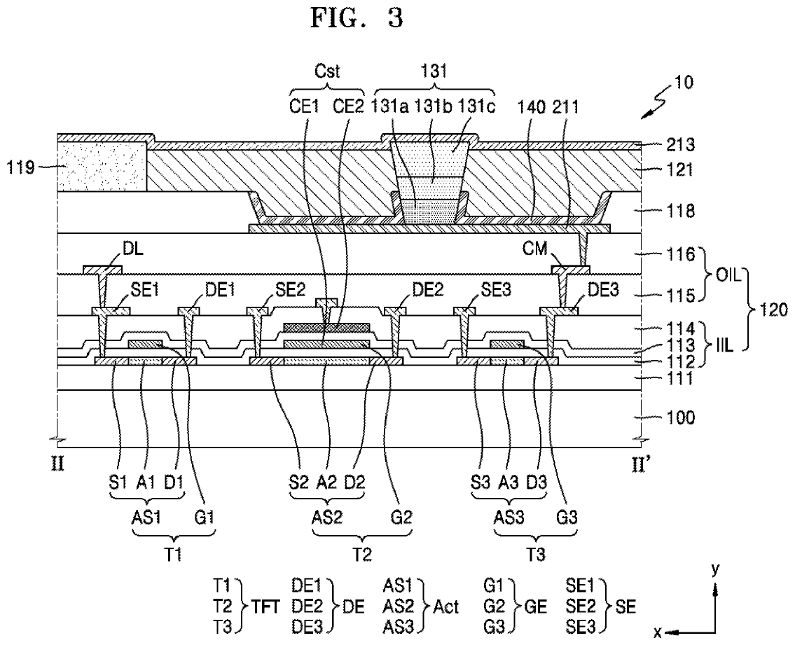

In an embodiment, a pixel circuit layer 120 may be arranged on the substrate 100. The pixel circuit layer 120 may be a layer including a circuit for driving the pixels 151, 152, and 153 to emit light. The pixel circuit layer 120 may include a semiconductor layer (see Act of FIG. 3), an organic insulating layer (see OIL of FIG. 3), an inorganic insulating layer (see IIL of FIG. 3), and a gate electrode (see GE of FIG. 3). In other words, the pixel circuit layer 120 including the semiconductor layer Act, the organic insulating layer OIL, the inorganic insulating layer IIL, and the gate electrode GE may be arranged on the substrate 100. The pixel circuit layer 120 will be described below in more detail.

In an embodiment, each of the first electrodes 211 may be spaced apart from each other and disposed on the pixel circuit layer 120. Micro light-emitting elements 130 may be coupled (or electrically connected) to the first electrode 211. A method of coupling (or electrically connecting) the micro light-emitting elements 130 to the first electrode 211 may include eutectic bonding, soldering, and an anisotropic conductive film (ACF) coupling method. Eutectic bonding may be a technique of bonding a wafer or chips at a low temperature using a low melting metal thin layer. The soldering method may be a method of melting and bonding two heterogeneous materials at a temperature of 450° C. or less by melting the low melting point insertion metal. The ACF coupling may be conducted by using an ACF, and the bonding may be conductive in a vertical direction and insulated in a horizontal direction.

In an embodiment, eutectic bonding may be used in a method of coupling (or electrically connecting) the micro light-emitting element 130 to the first electrode 211 considering the resolution of the panel and the process temperature of panel constituent materials. The micro light-emitting elements 130 may be in a form of a chip, and in order to couple (or electrically connect) the micro light-emitting elements 130 and the first electrode 211 by eutectic bonding, the first electrode 211 may be made of a high temperature common metal of greater than or equal to about 300 degrees. For example, the first electrode 211 may be made of a metal such as copper (Cu), tin (Sn), or gold (Au) considering material costs and processability. However, metals such as copper (Cu), tin (Sn), or gold (Au) have low reflectivity, and thus light transmittance of the micro light-emitting elements 130 may be degraded. In other words, light efficiency of the micro light-emitting elements 130 may be lowered. A reflector 140 including a metal having a reflectivity higher than a reflectivity of the first electrode 211 may be disposed on the display panel to increase light efficiency, which will be described below in more detail later.

The micro light-emitting element 130 may be coupled (or bonded) to the first electrode 211 by eutectic bonding. In other words, the first electrode 211 may function as a connection layer. The first electrode 211 and the reflector 140 may include different metal. The reflector 140 may include a first metal, and the first electrode 211 may include a second metal different from the first metal. The second metal for forming the first electrode 211 may be copper (Cu), tin (Sn) or gold (Au). In an embodiment, the first electrode 211 may be consist of a single layer including Cu, Sn or Au. In an embodiment, the first electrode 211 may include a compound of Cu, Sn, or Au. In an embodiment, the first electrode 211 may be consist of multiple layers including at least one of a layer made of Cu, a layer made of Sn, and a layer made of Au are stacked each other. However, embodiments of the disclosure are not limited thereto.

In an embodiment, a pixel-defining layer 118 including an opening 118OP exposing at least a portion of the first electrode 211 may be arranged on the first electrode 211. At least a portion of the first electrode 211 may be exposed by the opening 118OP. For example, at least a portion of the first electrode 211 may be exposed by a first opening 118OP1, a second opening 118OP2, and a third opening 118OP3 of the pixel-defining layer 118. A light-emitting region of light emitted from the micro light-emitting element 130 may be defined by the opening defined in the pixel-defining layer 118. For example, the width of the opening may correspond to the width of the light emitting region in a direction.

In an embodiment, the pixel-defining layer 118 may include an organic insulating material. In an embodiment, the pixel-defining layer 118 may include an inorganic insulating material such as silicon nitride, silicon oxynitride, or silicon oxide. In an embodiment, the pixel-defining layer 118 may include an organic insulating material and an inorganic insulating material. In an embodiment, the pixel-defining layer 118 may include a light-blocking material. The light-blocking material may be a resin or a paste including carbon black, carbon nanotubes, a black dye, metal particles such as nickel, aluminum, molybdenum, an alloy thereof, metal oxide particles (e.g., chromium oxide), metal nitride particles (e.g., chromium nitride), or the like. In case that the pixel-defining layer 118 includes a light blocking material, external light reflection due to metal structures disposed under the pixel-defining layer 118 may be reduced.

In an embodiment, the micro light-emitting elements 130 may be arranged in the openings 118OP1, 118OP2, and 118OP3 of the pixel-defining layer 118, respectively. The micro light-emitting elements 130 may be spaced apart from the pixel-defining layer 118 and may be arranged in the opening 118OP defined in the pixel-defining layer 118. The micro light-emitting elements 130 may be coupled (or electrically connected) to the first electrode 211 of which at least a portion is exposed by the openings 118OP of the pixel-defining layer 118. For example, a first micro light-emitting element 131 may be arranged on the first electrode 211 of which at least a portion is exposed by the first opening 180OP1 of the pixel-defining layer 118. For example, a second micro light-emitting element 132 may be arranged on the first electrode 211 of which at least a portion is exposed by the second opening 180OP2 of the pixel-defining layer 118. For example, a third micro light-emitting element 133 may be arranged on the first electrode 211 of which at least a portion is exposed by the third opening 118OP3 of the pixel-defining layer 118. The first micro light-emitting element 131, the second micro light-emitting element 132, and the third micro light-emitting element 133 may correspond to the first pixel 151, the second pixel 152, and the third pixel 153, respectively.

In an embodiment, each of the micro light-emitting elements 130 coupled (or electrically connected) to the first electrode 211 by eutectic bonding may be manufactured in the form of a micro-sized micro chip as a light-emitting diode that emits light of a color. Each of the micro light-emitting elements 130 may emit light of different wavelength bands. Each of the micro light-emitting elements 130 may constitute one pixel in the display panel. The first micro light-emitting element 131 may emit light of a color corresponding to the first pixel 151. For example, the first micro light-emitting element 131 may emit blue light. The second micro light-emitting element 132 may emit light of a color corresponding to the second pixel 152. For example, the second micro light-emitting element 132 may emit green light. The third micro light-emitting element 133 may emit light of a color corresponding to the third pixel 153. For example, the third micro light-emitting element 133 may emit red light.

In an embodiment, the reflector 140 may cover at least a portion of an inner surfaces of the openings 118OP of the pixel-defining layer 118, at least a portion of a top surface of the first electrode 211, and at least a portion of a side surface of the micro light-emitting element 130. The reflector 140 may be continuously disposed along at least a portion of the inner surfaces of the openings 118OP of the pixel-defining layer 118, a portion of the top surface of the first electrode 211 exposed by the openings 118OP, and at least a portion of the side surface of the micro light-emitting element 130. In an embodiment, a bottom surface of the micro light-emitting element 130 may be coupled (or electrically connected) to the first electrode 211, and the reflector 140 may surround along a lower side surfaces of the micro light-emitting elements 130.

The first electrode 211 may include a metal such as Cu, Sn, or Au so that the micro light-emitting element 130 may be coupled (or electrically connected) to the first electrode 211 by eutectic bonding. The metal such as Cu, Sn, or Au, may have low reflectivity, and in case that the first electrode 211 includes a metal such as Cu, Sn, or Au, a reflectivity of light may be reduced and transmittance (or light efficiency) of light generated by the micro light-emitting elements 130 may be lowered. The reflector 140 may be disposed on the display panel 10 to increase transmittance (or light efficiency) of light generated by the micro light-emitting element 130. By arranging the reflector 140 on the display panel 10, the reflectivity of light emitted in a downward direction (e.g., a direction to the first electrode 211) of light generated by the micro light-emitting element 130 may increase so that power consumption may be reduced through enhancement of light efficiency. For example, the reflectivity of blue light may be in a range of about 30 to about 40% before the reflector 140 is arranged, and the reflectivity of blue light may be improved to greater than or equal to about 90% after the reflector 140 is arranged.

A length L of a portion a micro light-emitting element 130 and a reflector 140 contact each other, may be in a range of about 0.1 μm to about 5 μm in a cross-sectional view. The length L of the reflector 140 covering at least a portion of the side surface of the micro light-emitting element 130 may be in a range of about 0.1 μm to about 5 μm. For example, the reflector 140 may surround the micro light-emitting element 130 with a height in a direction the side surface of a micro light-emitting element extends in a range of about 0.1 μm to about 5 μm along a lower side surface of the micro light-emitting element 130. In case that the length L of the portion the micro light-emitting element 130 and the reflector 140 contact each other, is less than about 0.1 μm, the reflector 140 may not be sufficient in the display panel 10 so that the reflectivity of light generated from the micro light-emitting element 30 may not increase, and thus light efficiency may not be improved. The height of the micro light-emitting element 130 (for example, the length in the y-axis direction) may be in a range of about 5 μm to about 7 μm. The length L of the portion the reflector 140 and the side surface of the reflector 140 contact each other, may be determined according to a height (e.g., a length in the y-axis direction) of the micro light-emitting element 130. In order to cover at least a portion of the side surface of the micro light-emitting element 130, the length L of the portion the reflector 140 and the micro light-emitting element 130 contact each other, may not exceed the height (for example, 5 to 7 μm) of the micro light-emitting element 130. In order to increase the reflectivity of light generated by the micro light-emitting element 130 and to contact at least a portion of the side surface of the micro light-emitting element 130, a length of the portion the micro light-emitting element 130 and the reflector 140 contact each other, may be in a range of about 0.1 μm to about 5 μm. However, embodiments of the disclosure are not limited thereto.

The reflector 140 may include a first metal. The first metal may include at least one of Ag and Al. A reflectivity of the first metal may be greater than a reflectivity of a second metal that constitutes the first electrode 211. In an embodiment, the reflector 140 may include a metal having higher reflectivity than a reflectivity of a metal included in the first electrode 211. For example, the reflector 140 may have a single layer structure including Ag, Al, or a conductive oxide (e.g., indium tin oxide (ITO)). In an embodiment, the reflector 140 may be provided as an alloy including a compound of Ag, Al, or a conductive oxide (e.g., ITO). The reflector 140 may include a multiple layers in which several layers of a layer formed of Ag, a layer formed of Al, or a layer formed of conductive oxide (e.g., ITO) are stacked each other. However, embodiments of the disclosure are not limited thereto.

In an embodiment, a black matrix 119 may be arranged on the pixel-defining layer 118. The black matrix 119 may define regions of pixels. The black matrix 119 may prevent light incident from the outside from being reflected. Also, the black matrix 119 may absorb light incident from the outside, thereby enhancing visibility of the display apparatus. The black matrix 119 may prevent light from leaking between pixels. In other words, the black matrix 119 may absorb lights emitted by the micro light-emitting element 130, thereby preventing lights generated by the micro light-emitting element 130 arranged in each of the pixels from being mixed with each other.

In an embodiment, an insulating layer 121 may be disposed on the pixel-defining layer 118 and the reflector 140. The insulating layer 121 may be filled between the black matrix 119 and the micro light-emitting element 130. For example, the insulating layer 121 may surround the side surface of the micro light-emitting element 130 and may be arranged on the pixel-defining layer 118 and the reflector 140. The insulating layer 121 may include an organic material. The insulating layer 121 may include an organic insulating material, such as a general use polymer such as polymethylmethacrylate (PMMA) or polystyrene (PS), a polymer derivative having a phenol-based group, an acryl-based polymer, an imide-based polymer, an aryl ether-based polymer, a fluorine-based polymer, a p-xylene-based polymer, a vinyl alcohol-based polymer, and a blend thereof. However, embodiments of the disclosure are not limited thereto.

In an embodiment, the second electrode 213 may be entirely formed on the black matrix 119, the insulating layer 121, and the micro light-emitting elements 130. The second electrode 213 may continuously cover the black matrix 119, the insulating layer 121, and the micro light-emitting elements 130. The second electrode 213 may include a conductive material having a small work function. For example, the second electrode 213 may include a (semi-)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy thereof. In an embodiment, the second electrode 213 may further include a layer including ITO, IZO, ZnO, or In₂O₃, on the (semi-)transparent layer including the above-described materials.

FIG. 2B is a schematic cross-sectional view of a display panel 10 according to another embodiment. Referring to FIG. 2B, the structure of the display panel 10 including the reflector 140 may be same as the display panel 10 according to the embodiment of FIG. 2A. However, an order or a stack structure in which the insulating layer 121, the second electrode 213, and the black matrix 119 are arranged, may be different from the display panel 10 according to the embodiment shown in FIG. 2A.

Referring to FIG. 2B, an insulating layer 121 may be disposed on the pixel-defining layer 118 and the reflector 140. The insulating layer 121 may be arranged on the pixel-defining layer 118 and the reflector 140 excluding a portion where the black matrix 119 is disposed. The insulating layer 121 may be filled between the second electrode 213, the black matrix 119, and the micro light-emitting element 130. In an embodiment, the insulating layer 121 may surround the side surface of the micro light-emitting element 130 and may be arranged on the pixel-defining layer 118 and the reflector 140.

In an embodiment, after the insulating layer 121 is arranged, the second electrode 213 may be continuously arranged on the pixel-defining layer 118 in which the insulating layer 121 is not arranged, the insulating layer 121, and the top surface and the side surface of the micro light-emitting element 130. For example, the second electrode 213 may continuously cover the top surface of the pixel-defining layer 118, the side surface and top surface of the insulating layer 121, and a partial side surface and top surface of the micro light-emitting element 130.

In an embodiment, after the second electrode 213 is continuously arranged, the black matrix 119 may be arranged on the pixel-defining layer 118. The second electrode 213 and the black matrix 119 may be sequentially arranged on the pixel-defining layer 118. For example, the second electrode 213 may be arranged along the bottom surface and at least a part of the side surface of the black matrix 119.

FIG. 3 is a schematic cross-sectional view of a display panel 10 according to an embodiment. In detail, FIG. 3 is a schematic cross-sectional view of the display panel 10 taken along II-II′ of FIG. 1. FIG. 3 is a schematic cross-sectional view of the first pixel 151 of the unit pixels 150, and the micro light-emitting element shown in FIG. 3 may be a first micro light-emitting element 131. A pixel circuit layer 120 of the display panel 10 will be described in detail with reference to FIG. 3.

Referring to FIG. 3, the display panel 10 may include a substrate 100, a pixel circuit layer 120 including an inorganic insulating layer IIL and an organic insulating layer OIL, a first electrode 211, a connection electrode CM, a data line DL, a first micro light-emitting element 131, a pixel-defining layer 118, a black matrix 119, a reflector 140, an insulating layer 121, and a second electrode 213. For example, the pixel circuit layer 120, the connection electrode CM, the data line DL, the first micro light-emitting element 131, the pixel-defining layer 118, the black matrix 119, the reflector 140, the insulating layer 121, and the second electrode 213 may be arranged on the substrate 100 of the display panel 10.

In an embodiment, the substrate 100 may include a glass material, a metal, or a polymer resin. In case that the substrate 100 includes a polymer resin, the substrate 100 may include a polymer resin such as polyethersulfone, polyarylate, polyetherimide, polyethylene naphthalate, polyethylene terephthalate, polyphenylene sulfide, polyimide, polycarbonate, cellulose triacetate, or cellulose acetate propionate.

Although not shown, the substrate 100 may include a first base layer, a first barrier layer, a second base layer, and a second barrier layer. In an embodiment, the first base layer, the first barrier layer, the second base layer, and the second barrier layer may be sequentially stacked in a thickness direction of the substrate 100.

The first barrier layer and the second barrier layer may be barrier layers for preventing penetration of external foreign substances, and may have a single layer or multi-layered structure including silicon nitride (SiN_{X}), silicon oxide (SiO₂) and/or silicon oxynitride (SiON).

A buffer layer 111 may be arranged on the substrate 100. The buffer layer 111 may include an inorganic insulating material such as silicon nitride (SiN_{X}), silicon oxynitride (SiON), and silicon oxide (SiO₂).

The inorganic insulating layer IIL may be arranged on the buffer layer 111. The inorganic insulating layer IIL may include a first gate insulating layer 112, a second gate insulating layer 113, and an interlayer insulating layer 114.

FIG. 3 illustrates three thin-film transistors (TFTs) T1, T2, and T3. The display panel 10 according to an embodiment may include a first TFT T1, a second TFT T2, and a third TFT T3. The transistors T1, T2, and T3 may act as switching transistors or driving transistors in a pixel circuit. However, embodiments of the disclosure are not limited thereto.

The first TFT T1 may include a first semiconductor layer AS1 and a first gate electrode G1. The first semiconductor layer AS1 may include a first source region S1, a first channel region A1, and a first drain region D1. The first gate electrode G1 may be arranged on the first semiconductor layer AS1. The first source region S1 may be connected to the first source electrode SE1 on the interlayer insulating layer 114, and the second source region D1 may be connected to the first drain electrode DE1 on the interlayer insulating layer 114. A data line DL may be disposed on the first organic insulating layer 115. The data line DL may be electrically connected to the first source electrode SE1 through a contact hole. However, embodiments of the disclosure are not limited thereto.

The second TFT T2 may include a second semiconductor layer AS2 and a second gate electrode G2. The second semiconductor layer AS2 may include a second source region S2, a second channel region A2, and a second drain region D2. The second gate electrode G2 may be arranged on the second semiconductor layer AS2. The second source region S2 may be connected to the second source electrode SE2 on the interlayer insulating layer 114, and the second source region D2 may be connected to the second drain electrode DE2 on the interlayer insulating layer 114. However, embodiments of the disclosure are not limited thereto.

The third TFT T3 may include a third semiconductor layer AS3 and a third gate electrode G3. The third semiconductor layer AS3 may include a third source region S3, a third channel region A3, and a third drain region D3. The third gate electrode G3 may be arranged on the third semiconductor layer AS3. The third source region S3 may be connected to the third source electrode SE3 on the interlayer insulating layer 114, and the third drain region D3 may be connected to the third drain electrode DE3 on the interlayer insulating layer 114. The connection electrode CM may be disposed on the first organic insulating layer 115. The connection electrode CM may be electrically connected to the third drain electrode DE3 through a contact hole. However, embodiments of the disclosure are not limited thereto.

Hereinafter, for convenience of explanation, the semiconductor layers AS1, AS2, and AS3 may be referred to as a semiconductor layer Act, and the gate electrodes G1, G2, and G3 may be referred to as a gate electrode GE. The thin film transistors T1, T2, and T3 may be referred to as TFTs, and the source electrodes SE1, SE2, and SE3 and the drain electrodes DE1, DE2, and DE3 may be referred to as a source electrode SE and a drain electrode DE.

The display panel 10 may include a pixel circuit layer 120 for driving a micro light-emitting element. The pixel circuit layer 120 may be arranged on the substrate 100 of the display panel 10. The pixel circuit layer 120 may include a TFT and a storage capacitor Cst. The TFT may include a semiconductor layer Act, a gate electrode GE, a source electrode SE, and a drain electrode DE. The storage capacitor Cst may include a lower electrode CE1 and an upper electrode CE2.

The semiconductor layer Act may be arranged on the buffer layer 111. In an embodiment, the semiconductor layer Act may include polysilicon. In an embodiment, the semiconductor layer Act may include amorphous silicon, an oxide semiconductor, or an organic semiconductor. The semiconductor layer Act may include channel regions A1, A2 or A3, drain regions D1, D2 or D3, and source regions S1, S2, and S3, which are arranged at each sides of the channel regions A1, A2 or A3, respectively.

The gate electrode GE may be arranged on the semiconductor layer Act. The gate electrode GE may overlap the channel regions A1, A2 or A3 in a plan view. The gate electrode GE may include a low-resistance metal. The gate electrode GE may include a conductive material including molybdenum (Mo), Al, Cu, and Ti, and may have a single layer or multi-layered structure including the above-described materials.

A first gate insulating layer 112 may be disposed between the semiconductor layer Act and the gate electrode GE. The first gate insulating layer 112 may include an inorganic insulating material, such as silicon oxide (SiO₂), silicon nitride (SiN_{X}), silicon oxynitride (SiON), aluminum oxide (Al₂O₃), titanium oxide (TiO₂), tantalum oxide (Ta₂O₅), hafnium oxide (HfO₂), or zinc oxide (ZnO).

A second gate insulating layer 113 may be arranged on the gate electrode GE. The second gate insulating layer 113 may be provided to cover the gate electrode GE. The second gate insulating layer 113 may include an inorganic insulating material, such as silicon oxide (SiO₂), silicon nitride (SiN_{X}), silicon oxynitride (SiON), aluminum oxide (Al₂O₃), titanium oxide (TiO₂), tantalum oxide (Ta₂O₅), hafnium oxide (HfO₂), or zinc oxide (ZnO).

An upper electrode CE2 of the storage capacitor Cst may be arranged on the second gate insulating layer 113. The upper electrode CE2 may overlap the second gate electrode G2 disposed thereunder in a plan view. In an embodiment, the second gate electrode G2 and the upper electrode CE2 that overlap each other with the second gate insulating layer 113 therebetween may form the storage capacitor Cst. For example, the second gate electrode G2 may function as a lower electrode CE1 of the storage capacitor Cst.

In an embodiment, the storage capacitor Cst and the second TFT T2 may overlap each other in a plan view. However, embodiments of the disclosure are not limited thereto. For example, the storage capacitor Cst may not overlap the second TFT T2. For example, the lower electrode CE1 of the storage capacitor Cst may be a separate component from the second gate electrode G2 of the second TFT T2 and may be spaced apart from the second gate electrode G2 of the second TFT T2.

The upper electrode CE2 may include Al, Pt, Pd, Ag, Mg, Au, Ni, Nd, Ir, Cr, Ca, Mo, Ti, W, and/or Cu, and may have a single layer or multilayered structure of the above-described materials.

An interlayer insulating layer 114 may be arranged on the upper electrode CE2. The interlayer insulating layer 114 may cover the upper electrode CE2. The interlayer insulating layer 114 may include an inorganic insulating material, such as silicon oxide (SiO₂), silicon nitride (SiN_{X}), silicon oxynitride (SiON), aluminum oxide (Al₂O₃), titanium oxide (TiO₂), tantalum oxide (Ta₂O₅), hafnium oxide (HfO₂), or zinc oxide (ZnO). The interlayer insulating layer 114 may have a single layer or multilayered structure including the above-described inorganic insulating material.

Each of the drain electrodes DE and the source electrodes SE may be located on the interlayer insulating layer 114. Each of the drain electrodes DE and the source electrodes SE may be connected to the semiconductor layer Act through a contact hole provided in the first gate insulating layer 112, the second gate insulating layer 113, and the interlayer insulating layer 114. The drain electrode DE and the source electrode SE may include a material having high conductivity. The drain electrode DE and the source electrode SE may include a conductive material including Mo, Al, Cu, and Ti, and may have a single layer or multi-layered structure including the above-described materials. For example, the drain electrode DE and the source electrode SE may have a multilayered structure of Ti/Al/Ti.

The organic insulating layer OIL may be arranged on the inorganic insulating layer K. The organic insulating layer OIL may include a first organic insulating layer 115 and a second organic insulating layer 116. FIG. 3 illustrates that two organic insulating layers OIL are provided. However, the disclosure is not limited thereto, and three or four organic insulating layers OIL may be provided.

The first organic insulating layer 115 may cover the drain electrode DE and the source electrode SE. The first organic insulating layer 115 may include an organic insulating material, such as a general use polymer such as polymethylmethacrylate (PMMA) or polystyrene (PS), a polymer derivative having a phenol-based group, an acryl-based polymer, an imide-based polymer, an aryl ether-based polymer, a fluorine-based polymer, a p-xylene-based polymer, a vinyl alcohol-based polymer, and a blend thereof.

A data line DL may be disposed on the first organic insulating layer 115. The data line DL may be connected to the source electrode SE1 of the first TFT T1 through a contact hole of the first organic insulating layer 115. The first TFT T1 may be a switching transistor. Although not shown, the first TFT T1 may transmit a data signal transmitted from the data line DL in response to a scan signal transmitted through a scan line. However, embodiments of the disclosure are not limited thereto.

The connection electrode CM may be disposed on the first organic insulating layer 115. The connection electrode CM may be connected to the drain electrode DE3 of the third TFT T3 through a contact hole of the first organic insulating layer 115. The connection electrode CM may include a material having high conductivity. The connection electrode CM may include a conductive material including Mo, Al, Cu, and Ti, and may have a single layer or multi-layered structure including the above-described materials. For example, the connection electrode CM may have a multi-layered structure of Ti/Al/Ti.

In an embodiment, a second organic insulating layer 116 may be disposed on the data line DL and the connection electrode CM. The second organic insulating layer 116 may cover the data line DL and the connection electrode CM. The second organic insulating layer 116 and the first organic insulating layer 115 may include a same material or different materials.

In an embodiment, a first electrode 211 and a first micro light-emitting element 131 may be arranged on the second organic insulating layer 116. In an embodiment, the first micro light-emitting element 131 may include an active layer 131b generating light, a first semiconductor layer 131a disposed on a lower surface of the active layer 131b and doped with a p-type dopant, and a second semiconductor layer 131c disposed on a top surface of the active layer 131b and doped with an n-type dopant. For example, an active layer 131b and a second semiconductor layer 131c may be sequentially stacked on the first semiconductor layer 131a.

The first semiconductor layer 131a may have p-type conductivity. For example, the first semiconductor layer 131a may be a layer doped with a p-type dopant. For example, the first semiconductor layer 131a may have p-type conductivity doped with a p-type dopant such as zinc (Zn), magnesium (Mg), cobalt (Co), nickel (Ni), copper (Cu), iron (Fe), or the like. The second semiconductor layer 131c may have n-type conductivity. For example, the second semiconductor layer 131c may be a layer doped with an n-type dopant. For example, the second semiconductor layer 131c may have n-type conductivity doped with an n-type dopant such as silicon (Si), germanium (Ge), tin (Sn), selenium (Se), tellurium (Te), or the like. The active layer 131b may be arranged between the first semiconductor layer 131a and the second semiconductor layer 131c and may generate light. The active layer 131b may emit light of a wavelength in case that holes provided from the first semiconductor layer 131a and electrons provided from the second semiconductor layer 131c are recombined, and may have a single quantum well structure or a multi-quantum well (MQW) structure by alternately stacking a well layer and a barrier layer each other. Light generated by the active layer 131b may be irradiated onto top, bottom, and side surfaces of the active layer 131b.

In an embodiment, a pixel-defining layer 118, a reflector 140, an insulating layer 121, a black matrix 119, and a second electrode 213 may be arranged on the second organic insulating layer 116 in addition to the first electrode 211 and the first micro light-emitting element 131. A structure disposed above the second organic insulating layer 116 in the display panel 10 has been described with reference to FIGS. 2A and 2B, and thus a description thereof will be omitted.

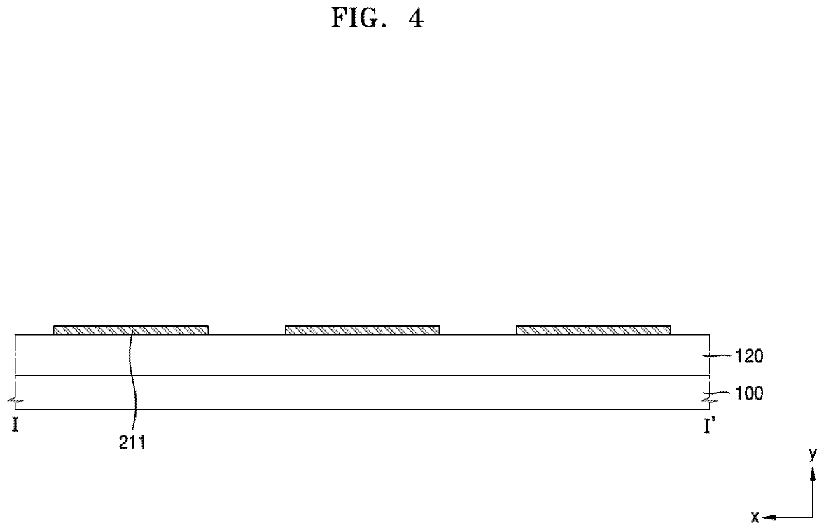

FIGS. 4 through 13 are schematic cross-sectional views of the display panel 10 schematically illustrating a method of manufacturing a display panel 10 according to an embodiment. FIGS. 4 through 10 are schematic cross-sectional views of the display panel 10 taken along line I-I′ of FIG. 1.

The method of manufacturing the display panel 10 may include forming a first electrode 211 on a substrate 100, forming a pixel-defining layer 118 including an opening 118OP exposing at least a portion of the first electrode 211, on the first electrode 211, coupling (or electrically connecting) the micro light-emitting element 130 to the first electrode 211, covering the pixel-defining layer 118, the first electrode 211, and the micro light-emitting element 130 with a material 141 for forming a reflector, filling the opening 118OP of the pixel-defining layer 118 to which the micro light-emitting element 130 is connected and which is covered with the material 141 for forming the reflector with a patterning layer 125, etching and removing an exposed portion of the material 141 for forming the reflector, and removing the patterning layer 125. The method of manufacturing the display panel 10 will be described in more detail below.

Referring to FIG. 4, first electrodes 211 may be arranged on the substrate 100. Each of the first electrodes 211 may be spaced apart from each other and disposed on the substrate 100. Micro light-emitting elements 130 may be coupled (or electrically connected) to the first electrode 211. The micro light-emitting elements 130 may be coupled (or electrically connected) to the first electrode 211 by a eutectic bonding method. The first electrodes 211 may function as a connection layer. In an embodiment, the first electrodes 211 may be consist of a single layer including Cu, Sn, or Au. In an embodiment, the first electrode 211 may include a compound of Cu, Sn, or Au. In an embodiment, the first electrode 211 may be consist of multiple layers including at least one of a layer made of Cu, a layer made of Sn, and a layer made of Au are stacked each other.

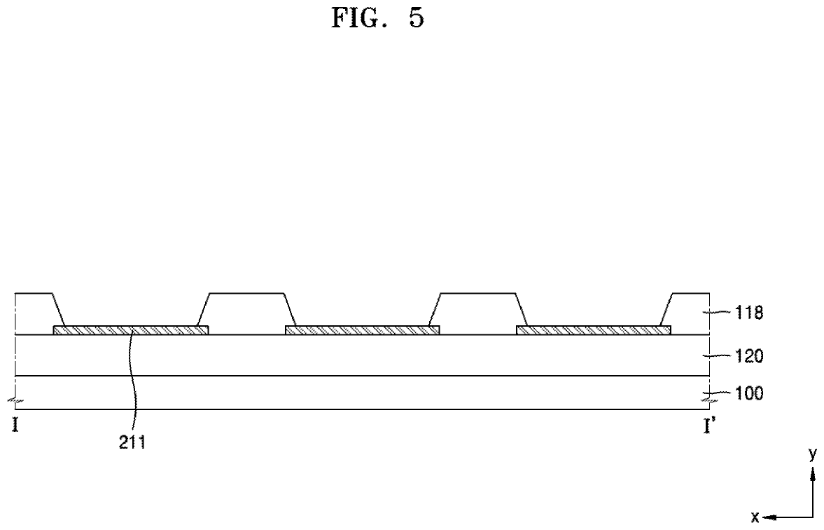

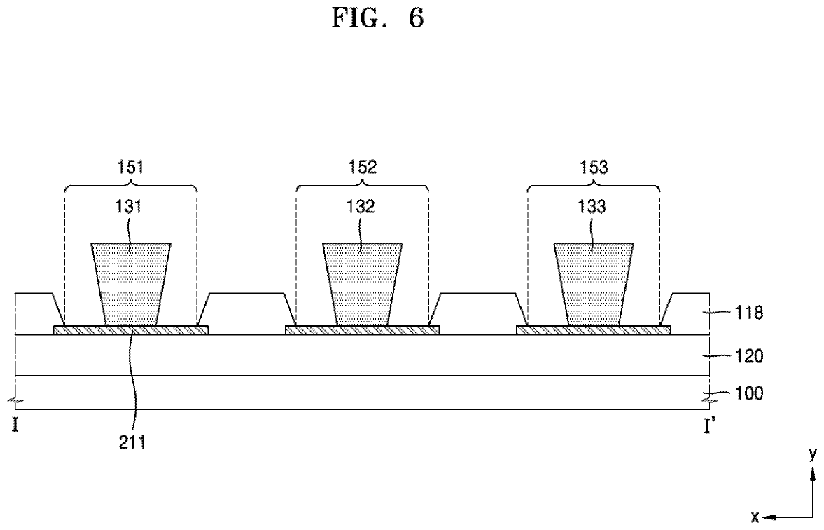

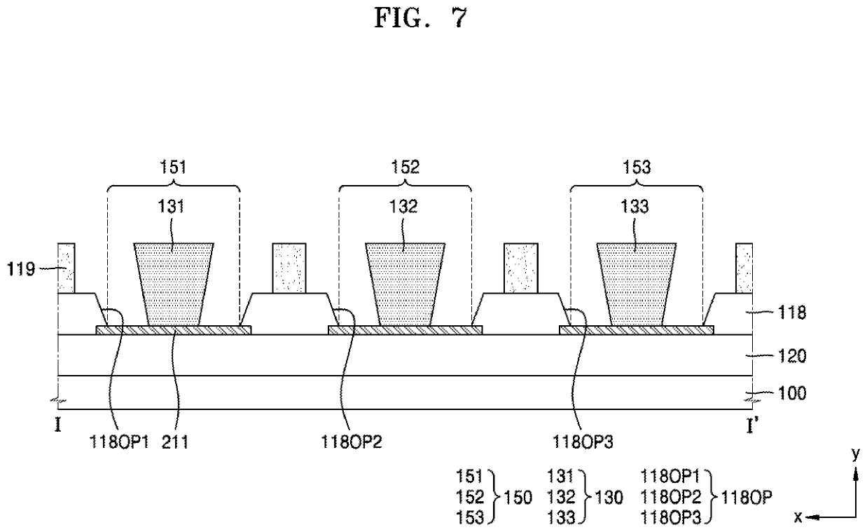

Referring to FIG. 5, a pixel-defining layer 118 including an opening 118OP exposing at least a portion of the first electrode 211 may be arranged on the first electrode 211. Referring to FIG. 6, micro light-emitting elements 130 may be arranged in the opening 118OP of the pixel-defining layer 118. For example, a first micro light-emitting element 131 may be arranged in the first opening 118OP1 (FIG. 7) of the pixel-defining layer 118, a second micro light-emitting element 132 may be arranged in the second opening 118OP2 (FIG. 7) of the pixel-defining layer 118, and a third micro light-emitting element 133 may be arranged in the third opening 118OP3 (FIG. 7) of the pixel-defining layer 118. In an embodiment, the width of the opening 118OP of the pixel-defining layer 118 may correspond to the width of the light-emitting region in a cross-sectional view.

Referring to FIG. 6, micro light-emitting elements 130 may be coupled (or electrically connected) to the first electrode 211. In an embodiment, the micro light-emitting elements 130 may be coupled (or electrically connected) to the first electrode 211 by a eutectic bonding method. In an embodiment, laser may be irradiated onto the first electrode 211 and the bottom surface of the micro light-emitting element 130 so that the micro light-emitting element 130 may be coupled (or electrically connected) to the first electrode 211 by eutectic bonding.

A first micro light-emitting element 131 coupled (or electrically connected) to the first electrode 211 may form a first pixel 151. A second micro light-emitting element 132 coupled (or electrically connected) to the first electrode 211 may form a second pixel 152. A third micro light-emitting element 133 coupled (or electrically connected) to the first electrode 211 may form a third pixel 153. In an embodiment, a first micro light-emitting element 131 forming a first pixel 151, a second micro light-emitting element 132 forming a second pixel 152, and a third micro light-emitting element 133 forming a third pixel 153 may emit light of different wavelengths. The display panel may display an image by light emitted from the first pixel 151, the second pixel 152, and the third pixel 153.

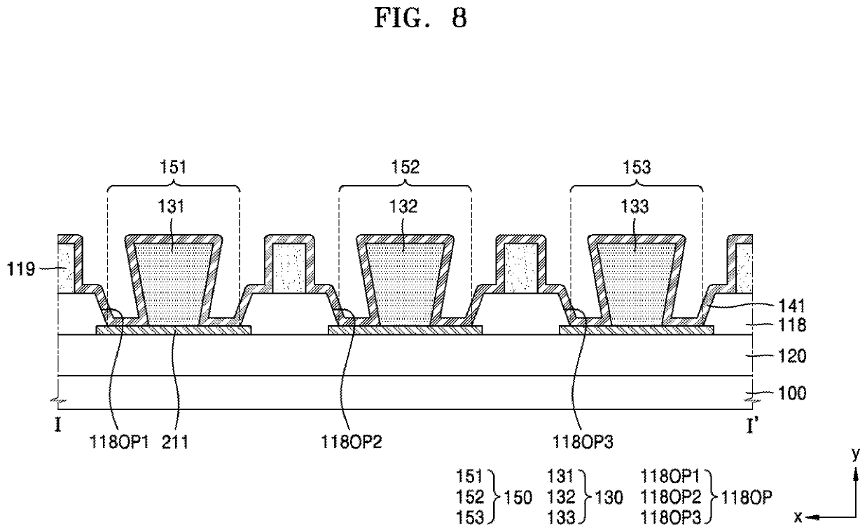

Referring to FIG. 7, a black matrix 119 may be arranged on the pixel-defining layer 118. The black matrix 119 may define regions of pixels. The black matrix 119 may prevent light from leaking between pixels. In an embodiment, the black matrix 119 may absorb lights emitted by the micro light-emitting elements 130, thereby preventing lights generated by the micro light-emitting elements 130 arranged in each of the pixels from being mixed with each other. In the display panel 10 according to an embodiment, the black matrix 119 may be directly arranged on a top surface of the pixel-defining layer 118, as shown in FIG. 7. In an embodiment, the black matrix 119 may be disposed on the pixel-defining layer 118 before the material (see 141 of FIG. 8) for forming a reflector is disposed on the display panel 10.

Referring to FIG. 8, the material 141 for forming a reflector may be formed on the black matrix 119, the pixel-defining layer 118, the first electrode 211, and the top surface and side surface of the micro light-emitting elements 130. In an embodiment, the material 141 for forming the reflector may continuously cover along the black matrix 119, the pixel-defining layer 118, the first electrode 211, and the top surface and side surface of the micro light-emitting elements 130.

Metals such as copper (Cu), tin (Sn), or gold (Au) of the first electrode 211 may have low reflectivity, and thus light transmittance generated from the micro light-emitting elements 130 may be degraded. The reflector 140 may be arranged on the pixel circuit layer 120 so that the reflectivity of light generated by the micro light-emitting element 130 may be enhanced.

The reflector 140 may have a first reflectivity and the first electrode 211 may have a second reflectivity, and the first reflectivity may be higher than the second reflectivity. For example, the reflectivity of the reflector 140 may be higher than the reflectivity of the first electrode 211. However, embodiments of the disclosure are not limited thereto.

In an embodiment, the material 141 for forming the reflector may include Ag, Al, or a compound thereof. In an embodiment, the material 141 for forming the reflector may include a conductive oxide (e.g., indium tin oxide (ITO). In an embodiment, the material 141 for forming the reflector may be an alloy layer including a compound of Ag, Al, or a conductive oxide (e.g., ITO).

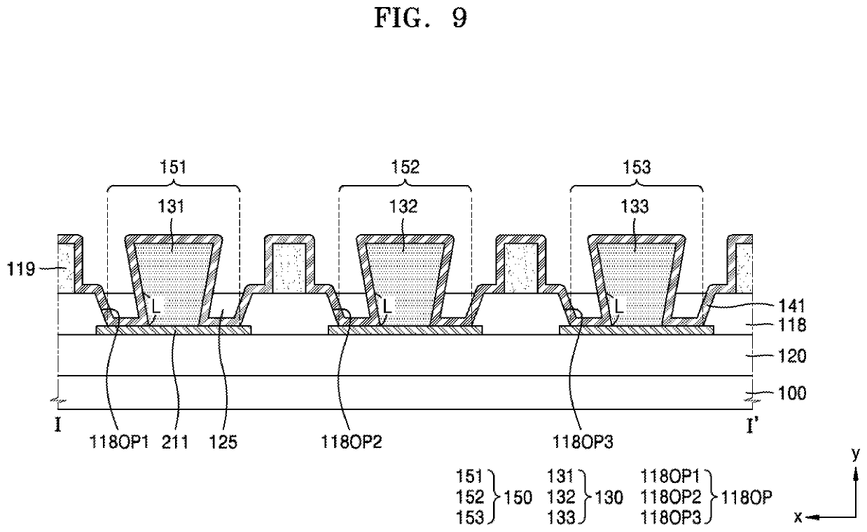

Referring to FIG. 9, the opening 118OP of the pixel-defining layer 118 where the micro light-emitting element 130 is coupled (or electrically connected) and covered by the material 141 for forming the reflector may be filled with a patterning layer 125. In an embodiment, the patterning layer 125 may be an organic layer. In an embodiment, the patterning layer 125 may be a photoresist.

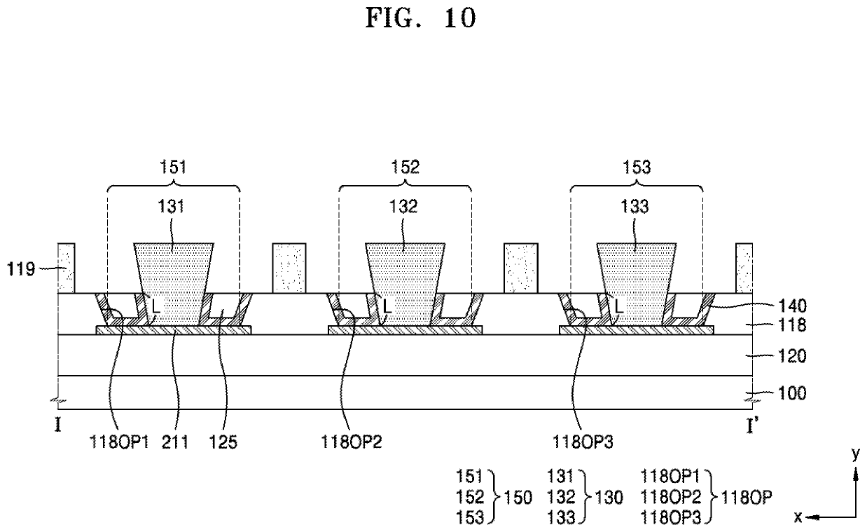

During an etching process, an exposed portion of the material 141 for forming the reflector not covered by the patterning layer 125 may be removed, and a portion of the material 141 for forming the reflector covered by the patterning layer 125 may not be etched and may remain. A length L of the material 141 for forming the reflector covered with the patterning layer 125 may vary according to the degree (or depth) of which the patterning layer 125 is filled. For example, the length L of the material 141 for forming the reflector that is not etched and remains may vary according to the degree (or depth) of which the patterning layer 125 is filled. The length (see L of FIG. 10) of a portion where the reflector 140 contacts the micro light-emitting element 130, may vary according to the degree (or depth) of which the patterning layer 125 is filled.

In an embodiment, the length L of the reflector 140 contacting the micro light-emitting element 130 in a cross-sectional view may be in a range of about 0.1 μm to about 5 μm. The length (see L of FIG. 10) of which the reflector 140 and the micro light-emitting element 130 contact each other, may vary according to the degree (or depth) of which the patterning layer 125 is filled in the opening of the pixel-defining layer 118. For example, the patterning layer 125 may be filled in the opening 118OP of the pixel-defining layer 118 such that a length between the top surface of the patterning layer 125 and the top surface of the first electrode 211 in a direction the side surface of the micro light-emitting element 130 extends is in a range of about 0.1 μm to about 5 μm.

Referring to FIG. 10, the reflector 140 that covers the inner surface of the opening 118OP of the pixel-defining layer 118, the first electrode 211, and at least a portion of the side surface of the micro light-emitting element 130 may be formed.

In an embodiment, the reflector 140 may be provided as a single layer including Ag, Al, or a conductive oxide (e.g., ITO). In an embodiment, the reflector 140 may be provided as an alloy layer including a compound of Ag, Al, or a conductive oxide (e.g., ITO). The reflector 140 may have a structure in which a layer including silver (Ag), aluminum (Al), or a compound thereof and a layer including a conductive oxide (e.g., ITO) are stacked each other. For example, the material 141 for forming the reflector may have a structure in which a layer including silver (Ag), aluminum (Al), or a compound thereof and a layer including a conductive oxide (e.g., ITO) are stacked each other.

After the patterning layer 125 is disposed in the opening 118OP of the pixel-defining layer 118, a portion of the materials 141 for forming the reflector not covered by the patterning layer 125, for example, an exposed portion of the materials 141 for forming the reflector not covered by the patterning layer 125, may be removed by an etching process. On the other hand, the material 141 for forming the reflector covered (or arranged) by the patterning layer 125 may not be removed. The patterning layer 125 may prevent the material 141 for forming the reflector disposed thereunder from being etched. A length L of which the reflector 140 and the micro light-emitting element 130 contact each other, may be in a range of about 0.1 μm to about 5 μm.

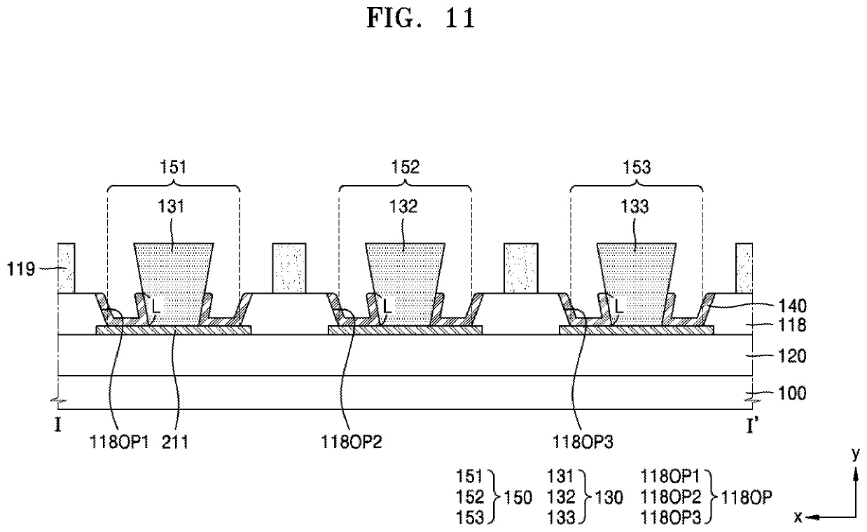

Referring to FIG. 11, after the material 141 for forming a reflector not covered by the patterning layer 125 is removed by an etching process, the patterning layer 125 filled in the opening 118OP of the pixel-defining layer 118 may be removed. Since the patterning layer 125 is used to selectively etch the material 141 for forming the reflector, the patterning layer 125 may be removed.

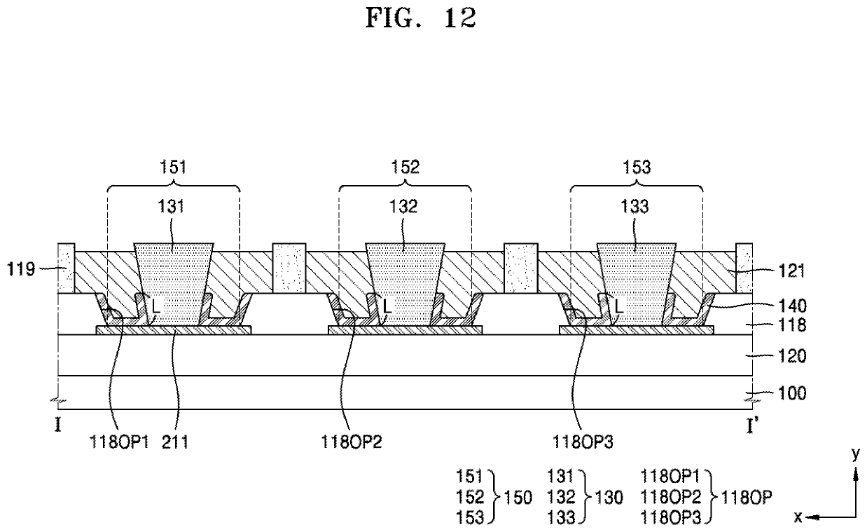

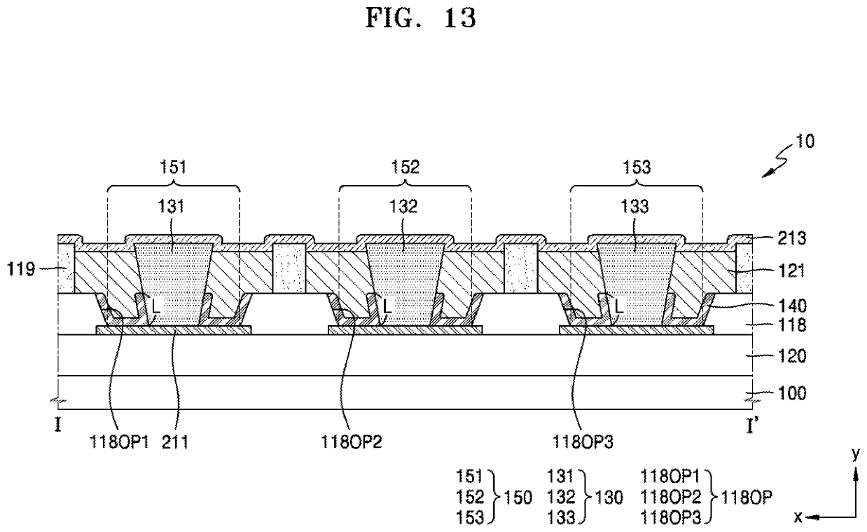

Referring to FIGS. 12 and 13, an insulating layer 121 may be disposed on the pixel-defining layer 118 and the reflector 140. The insulating layer 121 may be filled between the micro light-emitting element 130 and the black matrix 119. In an embodiment, the insulating layer 121 may surround the side surface of the micro light-emitting element 130. The insulating layer 121 may include an organic material.

After the insulating layer 121 is filled between the black matrix 119 and the micro light-emitting element 130, the second electrode 213 may be arranged on the black matrix 119, the insulating layer 121, and the micro light-emitting element 130. The second electrode 213 may entirely cover the top surface of the display panel 10. For example, the second electrode 213 may continuously cover the black matrix 119, the insulating layer 121, and the micro light-emitting elements 130.

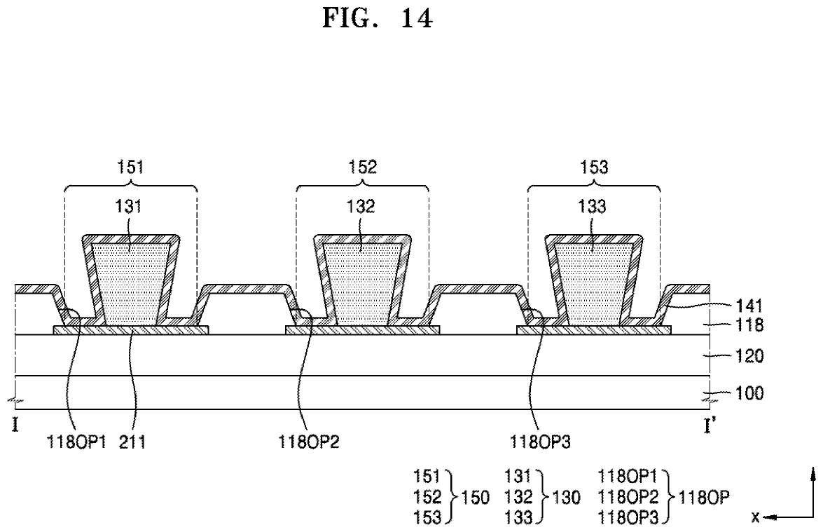

FIGS. 14 through 20 are schematic cross-sectional views schematically illustrating a method of manufacturing the display panel 10 according to another embodiment. FIGS. 14 through 20 are schematic cross-sectional views of the display panel 10 taken along line I-I′ of FIG. 1. The manufacturing method of the display panel 10 according to another embodiment of the disclosure according to FIGS. 14 to 20 is same as the manufacturing method of the display panel 10 according to the embodiment of FIGS. 4 to 6, but the following processes may be different. For example, the method of manufacturing the display panel 10 according to another embodiment of the disclosure may be partially different in the stacking order of the black matrix 119 and the second electrode 213 arranged on the pixel-defining layer 118.

In a method of manufacturing the display panel 10 according to another embodiment of the disclosure, each of the first electrode 211 may be spaced apart from each other and disposed on the substrate 100, as described with reference to FIGS. 4 to 6, and a pixel-defining layer 118 exposing at least a portion of the first electrode 211 may be disposed on the first electrode 211. After the pixel-defining layer 118 is arranged, the micro light-emitting element 130 may be coupled (or electrically connected) by eutectic bonding to the first electrode 211.

Referring to FIG. 14, a material 141 for forming a reflector may cover the pixel-defining layer 118, the first electrode 211, and the top surface and side surface of the micro light-emitting elements 130. The material 141 for forming the reflector may be arranged entirely on the pixel-defining layer 118. In an embodiment, a black matrix 119 may not be arranged on the pixel-defining layer 118.

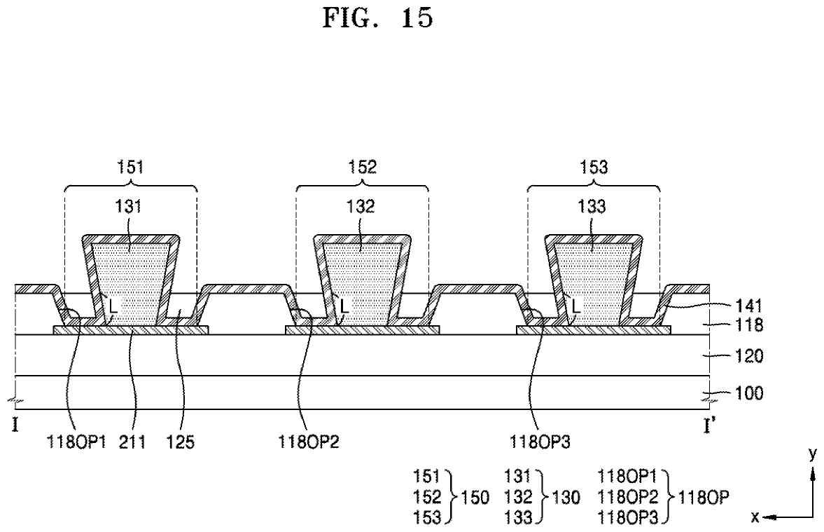

Referring to FIG. 15, the opening 118OP of the pixel-defining layer 118 covered by the material 141 for forming the reflector and where the micro light-emitting element 130 is coupled (or electrically connected) may be filled with the patterning layer 125. In an etching process, an exposed portion of the material 141 for forming the reflector not covered by the patterning layer 125 may be removed by etching, and a portion of the material 141 for forming the reflector covered by the patterning layer 125 may not be etched and may remain. A length of the material 141 for forming a reflector remaining without being etched may vary according to the height of the patterning layer 125 filled in the opening 118OP of the pixel-defining layer 118. The patterning layer 125 may be filled in the opening 118OP of the pixel-defining layer 118 so that a length L of which the reflector 140 and the micro light-emitting element 130 contact each other, may be in a range of about 0.1 μm to about 5 μm.

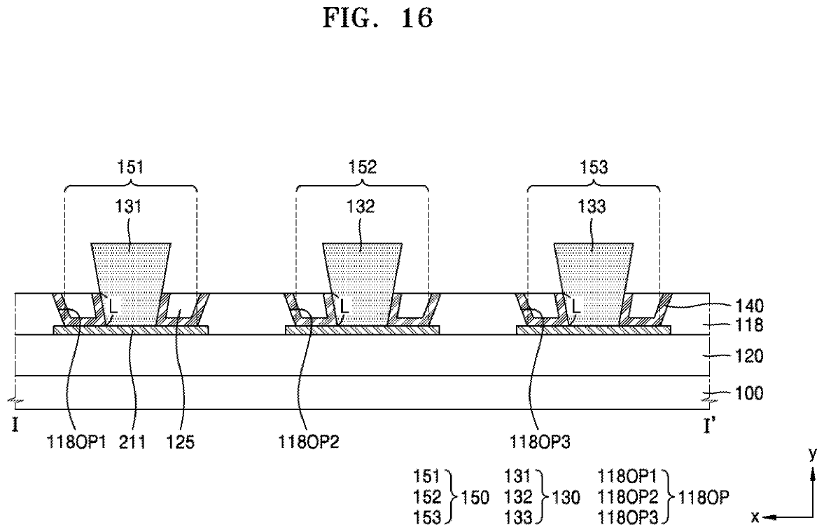

Referring to FIG. 16, the reflector 140 that covers the inner surface of the opening 118OP of the pixel-defining layer 118, the first electrode 211, and at least a portion of the side surface of the micro light-emitting element 130 may be formed. The material 141 for forming the reflector that is not covered with the patterning layer 125 and is exposed, may be removed through an etching process, and the material 141 for forming the reflector covered with the patterning layer 125 may not be etched and may remain so that the reflector 140 may be formed. A length L of which the reflector 140 and the micro light-emitting element 130 contact each other in a cross-sectional view, may be in a range of about 0.1 μm to about 5 μm.

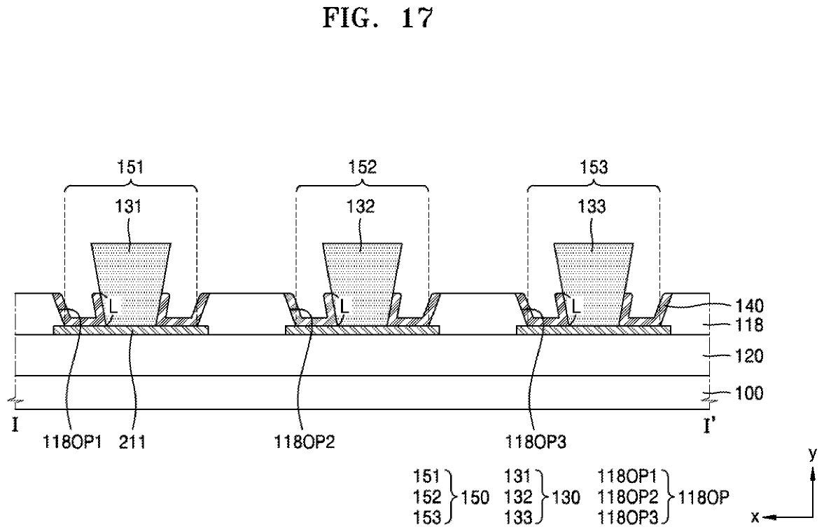

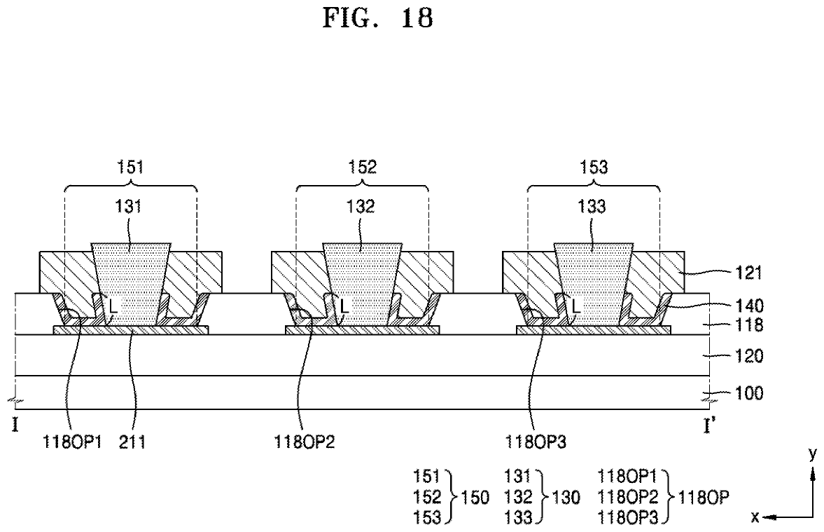

Referring to FIGS. 17 and 18, after the material 141 for forming the reflector is partially etched to form the reflector 140, the patterning layer 125 filled in the opening 118OP of the pixel-defining layer 118 may be removed.

After the patterning layer 125 filled in the opening 118OP of the pixel-defining layer 118 is removed, an insulating layer 121 may be formed on the pixel-defining layer 118 and the reflector 140. The insulating layer 121 may be formed to surround the micro light-emitting element 130, and the insulating layers 121 may be spaced apart from each other with the pixel-defining layer 118 interposed therebetween.

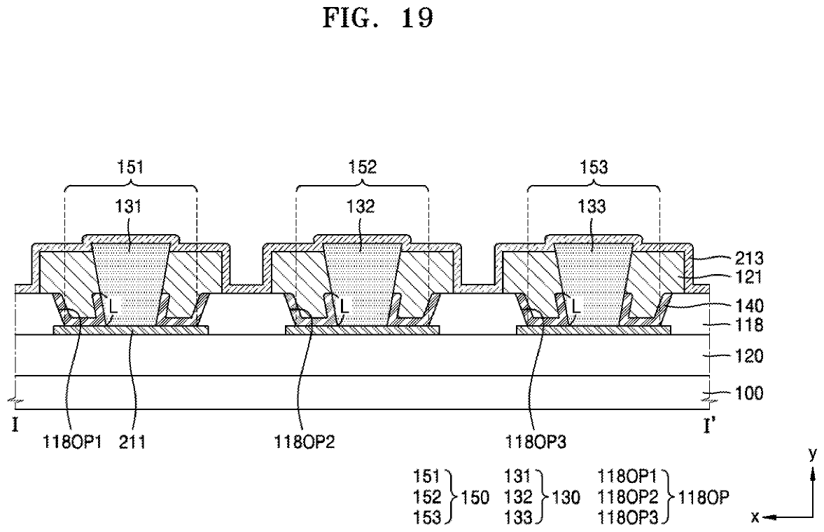

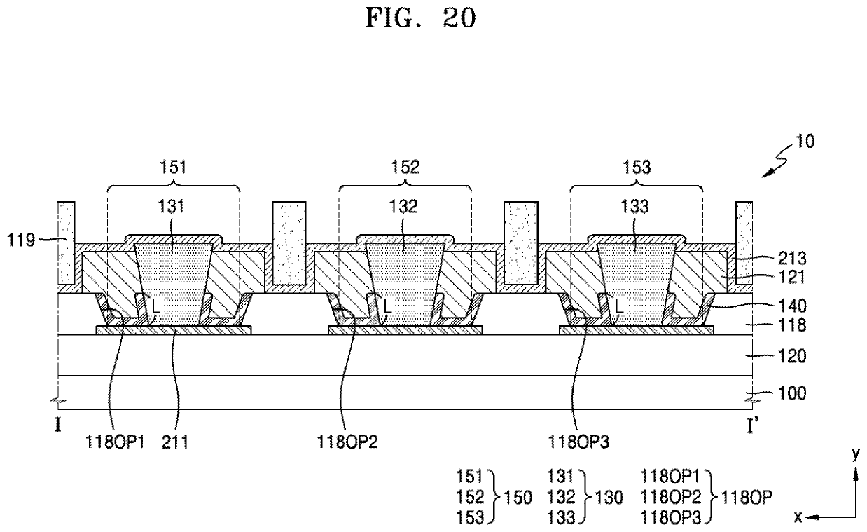

Referring to FIGS. 19 and 20, after the insulating layer 121 is formed, the second electrode 213 may be entirely formed on an upper surface and a side surface of the pixel-defining layer 118, the insulating layer 121, and the micro light-emitting element 130. A portion of the second electrode 213 may be directly disposed on the upper surface of the pixel-defining layer 118. Also, a portion of the second electrode 213 may be arranged along the side surface of the insulating layer 121. However, embodiments of the disclosure are not limited thereto.

In an embodiment, after the second electrode 213 is entirely formed on the display panel 10, a black matrix 119 may be formed on a portion of the pixel-defining layer 118 on which the insulating layer 121 is not disposed. A portion of the second electrode 213 may be disposed on a lower surface of the black matrix 119 disposed on the pixel-defining layer 118. Also, the second electrode 213 may be arranged between side surfaces of the black matrix 119 and the insulating layer 121.

A method of coupling (or electrically connecting) the micro light-emitting elements 130 to the first electrode 211 may include eutectic bonding, soldering, and an anisotropic conductive film (ACF) coupling method. In an embodiment, eutectic bonding may be used in a method of coupling (or electrically connecting) the micro light-emitting element 130 to the first electrode 211 considering the resolution of the panel and the process temperature of panel constituent materials.

In order to eutectic bond the micro light-emitting element 130 to the first electrode 211, the first electrode 211 may be formed of a metal such as Cu, Sn, or Au in consideration of material costs and processability. However, metals such as Cu, Sn, or Au may have low reflectivity, and thus light transmittance generated from the micro light-emitting elements 130 may be degraded.

In order to increase the light efficiency of the display panel 10, the reflectivity of light generated by the micro light-emitting element 130 may be increased. The reflector 140 including a metal having a higher reflectivity than the metal included in the first electrode 211 may be disposed on the display panel 10 to increase the reflectivity of light generated from the micro light-emitting element 130, thereby improving light efficiency.

The reflector 140 may be arranged along the inner surface of the opening 118OP of the pixel-defining layer 118, the first electrode 211, and at least a portion of the side surface of the micro light-emitting element 130. In an embodiment, the reflector 140 may include Ag, Al, or a compound thereof. In an embodiment, the reflector 140 may include a conductive oxide (e.g., ITO).

In a display panel and a method of manufacturing the display panel according to embodiments, light efficiency of the display panel may be enhanced.

The above description is an example of technical features of the disclosure, and those skilled in the art to which the disclosure pertains will be able to make various modifications and variations. Thus, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display panel comprising:
a substrate;
a first electrode disposed on the substrate;
a pixel-defining layer disposed on the first electrode and including an opening exposing at least a portion of the first electrode;
a micro light-emitting element electrically connected to the first electrode; and
a reflector disposed on the first electrode and covering at least a portion of a side surface of the micro light-emitting element.

2. The display panel of claim 1, wherein
the reflector has a first reflectivity, and
the first electrode has a second reflectivity lower than the first reflectivity.

3. The display panel of claim 1, the reflector is disposed directly on a top surface of the first electrode.

4. The display panel of claim 1, the reflector comprises a first metal.

5. The display panel of claim 4, wherein the first metal is silver (Ag), aluminum (Al), a compound of silver, or a compound of aluminum.

6. The display panel of claim 1, the reflector comprises a conductive oxide.

7. The display panel of claim 4, wherein the reflector comprises at least two layers including a first layer including the first metal and a second layer including a conductive oxide.

8. The display panel of claim 1, wherein a length of which the reflector and the side surface of the micro light-emitting element contact each other in a cross-sectional view is in a range of about 0.1 μm to about 5 μm.

9. The display panel of claim 1, wherein the first electrode and the micro light-emitting element are electrically to each other by eutectic bonding.

10. The display panel of claim 4, wherein the first electrode comprises a second metal different from the first metal.

11. The display panel of claim 10, wherein the second metal is copper (Cu), tin (Sn), gold (Au), a compound of copper, a compound of tin, or a compound of gold.

12. The display panel of claim 1, further comprising:
a black matrix disposed on the pixel-defining layer; and
an insulating layer disposed on the reflector and a portion of the pixel-defining layer.

13. The display panel of claim 12, wherein the insulating layer is disposed between the micro light-emitting element and the black matrix.

14. The display panel of claim 12, further comprising:
a second electrode disposed on the insulating layer and the micro light-emitting element.

15. The display panel of claim 14, the second electrode is disposed on the black matrix.

16. The display panel of claim 14, wherein the second electrode is disposed between the pixel-defining layer and the black matrix.

17. A method of manufacturing a display panel, the method comprising:
forming a first electrode on a substrate;
forming, on the first electrode, a pixel-defining layer including an opening exposing at least a portion of the first electrode;
electrically connecting a micro light-emitting element to the first electrode;
forming a material for forming a reflector on the pixel-defining layer, the first electrode, and the micro light-emitting element;
forming a patterning layer in the opening of the pixel-defining layer in which the micro light-emitting element is electrically connected and covered with the material for forming the reflector;
etching and removing an exposed portion of the material for forming the reflector; and
removing the patterning layer.

18. The method of claim 17, further comprising:
forming an insulating layer on the pixel-defining layer and the reflector; and
forming a second electrode on the insulating layer.

19. The method of claim 18, further comprising:
forming a black matrix on the pixel-defining layer;
wherein the second electrode is formed on the black matrix.

20. The method of claim 17, further comprising:
forming an insulating layer on the pixel-defining layer and the reflector;
forming a second electrode on the pixel-defining layer and the insulating layer; and
forming a black matrix on the second electrode.
